(19) United States
(12) Patent Application Publication
(10) Pub. No.: US 2012/0145234 A1
(43) Pub. Date: Jun. 14, 2012

(54) GRAPHENE ELECTRODES FOR SOLAR CELLS

(75) Inventors: Joseph D. ROY-MAYHEW, Princeton, NJ (US); Ilhan A. Aksay, Princeton, NJ (US)

(73) Assignee: The Trustees of Princeton University, Princeton, NJ (US)

(21) Appl. No.: 13/269,888

(22) Filed: Oct. 10, 2011

Related U.S. Application Data
(60) Provisional application No. 61/391,668, filed on Oct. 10, 2010.

(51) Int. Cl. H01L 31/0224; H01L 31/18; B82Y 99/00

(52) U.S. Cl. 136/256; 438/98; 257/E31.124; 977/734

(57) ABSTRACT

Electrodes for dye-sensitized solar cells comprising graphene sheets and at least one binder. The electrodes may be conductive and catalytic counter electrodes. The electrodes may be flexible.

### REFERENCE TO RELATED APPLICATIONS

The present application claims priority to U.S. Provisional Application No. 61/391,668 filed Oct. 10, 2010, the entire contents of which are hereby incorporated by reference.

### STATEMENT REGARDING FEDERALLY SPONSORED RESEARCH AND DEVELOPMENT

This invention was made with government support under grant number W911 NF-09-1-0476 awarded by the Army Research Office and grant number DE-AC05-76RL01830 awarded by the Department of Energy. The government has certain rights in the invention.

### FIELD OF THE INVENTION

The present invention relates to the use of graphene electrodes in solar cells.

### BACKGROUND

Generally speaking, photovoltaic systems are implemented to convert light energy into electricity for a variety of applications. Power production by photovoltaic systems may offer a number of advantages over conventional systems. These advantages may include, but are not limited to, low operating costs, high reliability, modularity, low construction costs, and environmental benefits. As can be appreciated, photovoltaic systems are commonly known as “solar cells,” so named for their ability to produce electricity from sunlight.

Conventional solar cells convert light into electricity by exploiting the photovoltaic effect that exists at semiconductor junctions. Accordingly, conventional semiconductor layers generally absorb incoming light to produce excited electrons. In addition to the semiconductor layers, solar cells generally include a cover or other encapsulant, seals on the edges of the solar cell, a front contact electrode to allow the electrons to enter a circuit, and a back contact electrode to allow the electrons to complete the circuit.

One particular type of solar cell is a dye-sensitized solar cell (DSSC). A DSSC generally uses an organic or organo-metalic dye to absorb incoming light to produce excited electrons. The DSSC generally includes two planar conducting electrodes arranged in a sandwich configuration. A dye-coated semiconductor film separates the two electrodes which may comprise glass coated with a transparent conducting oxide (TCO) film, for example. The semiconductor layer can be porous and has a high surface area thereby allowing sufficient dye for efficient light absorption to be attached as a molecular monolayer on its surface. The intervening space between the electrodes and the pores in the semiconductor film (which acts as a sponge) can be filled with a hole conductor, such as a conducting polymer or organic electrolyte solution containing an oxidation/reduction couple (triiodide/iodide, for example). For cases where a redox couple is used, a catalyst, platinum for example, is deposited on the second electrode (cathode).

One exemplary technique for fabricating a DSSC is to coat a conductive glass plate with a semiconductor film such as titanium dioxide (TiO₂) or zinc oxide (ZnO), for example. The semiconductor film is saturated with a dye and a layer of dye molecules self-assembles on each of the particles in the semiconductor film, thereby “sensitizing” the film. A liquid electrolyte solution containing triiodide/iodide is introduced into the semiconductor film. The electrolyte fills the pores and openings left in the dye-sensitized semiconductor film. To complete the solar cell, a second planar electrode coated with platinum—a material with low overpotential for triiodide reduction—is implemented to provide a cell structure having a dye-sensitized semiconductor and electrolyte composite sandwiched between two electrodes.

Platinum has high catalytic activity towards triiodide reduction and is sufficiently corrosion-resistant to iodo species present in the electrolyte. However, since platinum is a precious metal, much incentive exists to develop DSSC counter electrodes using cheaper, abundant materials. It would also be desirable to obtain easy to handle, conductive, and flexible DSSC counter electrodes.

Gruner, U.S. Published Application 2007/0284557 discloses the use of graphene films as a transparent conductor for use in solar cells., Electrochemistry Communications 2008, 10, (10), 1555-1558 discloses the use of a chemically reduced graphite oxide derived graphene/poly(3,4-ethylenedioxythiophene) poly(styrene sulfonate) composite in DSSCs. Sol. Energy Mater. Sol. Cells; DOI=10.1016/j.solmat.2010.04.044 discloses dye-sensitized solar cells using graphene-based carbon nanotube nanocomposites as counter electrodes.

### SUMMARY OF THE INVENTION

Disclosed and claimed herein is a solar cell electrode, comprising a composition comprising graphene sheets and at least one binder. Further disclosed and claimed herein are a dye-sensitized solar cell comprising the electrode and a method of making a dye-sensitized solar cell electrode, comprising incorporating an electrode comprising a composition comprising graphene sheets and at least one binder into a solar cell.

### DETAILED DESCRIPTION OF THE INVENTION

The solar cell electrodes of the invention can be made by coating compositions comprising graphene sheets and at least one binder onto a substrate. The electrodes may be incorporated into solar cells (such as dye-sensitized solar cells) and may be used as catalytic counter electrodes in solar cells, including dye-sensitized solar cells.

The graphene sheets are graphite sheets preferably having a surface area of from about 100 to about 2630 m²/g. In some embodiments, the graphene sheets primarily, almost completely, or completely comprise fully exfoliated single sheets of graphite (these are approximately 1 nm thick and are often referred to as “graphene”), while in other embodiments, at least a portion of the graphene sheets may comprise at partially exfoliated graphite sheets, in which two or more sheets of graphite have not been exfoliated from each other. The graphene sheets may comprise mixtures of fully and partially exfoliated graphite sheets.

Graphene sheets may be made using any suitable method. For example, they may be obtained from graphite, graphite oxide, expandable graphite, expanded graphite, etc. They may be obtained by the physical exfoliation of graphite, by for example, peeling off sheets graphene sheets. They may be made from inorganic precursors, such as silicon carbide. They may be made by chemical vapor deposition (such as by reacting a methane and hydrogen on a metal surface). They may be made by the reduction of an alcohol, such ethanol, with a metal (such as an alkali metal like sodium) and the subsequent pyrolysis of the alkoxide product (such a method is reported in Nature Nanotechnology (2009), 4, 30-33). They may be made by the exfoliation of graphite in dispersions or exfoliation of graphite oxide in dispersions and the subsequently reducing the exfoliated graphite oxide. Graphene sheets may be made by the exfoliation of expandable graphite, followed by intercalation, and ultrasonication or other means of separating the intercalated sheets (see, for example, Nature Nanotechnology (2008), 3, 538-542). They may be made by the intercalation of graphite and the subsequent exfoliation of the product in suspension, thermally, etc.

Graphene sheets may be made from graphite oxide (also known as graphitic acid or graphene oxide). Graphite may be treated with oxidizing and/or intercalating agents and exfoliated. Graphite may also be treated with intercalating agents and electrochemically oxidized and exfoliated. Graphene sheets may be formed by ultrasonically exfoliating suspensions of graphite and/or graphite oxide in a liquid (which may contain surfactants and/or intercalants). Exfoliated graphite oxide dispersions or suspensions can be subsequently reduced to graphene sheets. Graphene sheets may also be formed by mechanical treatment (such as grinding or milling) to exfoliate graphite or graphite oxide (which would subsequently be reduced to graphene sheets).

Reduction of graphite oxide to graphene may be by means of chemical reduction and may be carried out in graphite oxide in a solid form, in a dispersion, etc. Examples of useful chemical reducing agents include, but are not limited to, hydrazines (such as hydrazine, N,N-dimethylhydrazine, etc.), sodium borohydride, citric acid, hydroquinone, isocyanates (such as phenyl isocyanate), hydrogen, hydrogen plasma, etc. A dispersion or suspension of exfoliated graphite oxide in a carrier (such as water, organic solvents, or a mixture of solvents) can be made using any suitable method (such as ultrasonication and/or mechanical grinding or milling) and reduced to graphene sheets.

Graphite oxide may be produced by any method known in the art, such as by a process that involves oxidation of graphite using one or more chemical oxidizing agents and, optionally, intercalating agents such as sulfuric acid. Examples of oxidizing agents include nitric acid, sodium and potassium nitrates, perchlorates, hydrogen peroxide, sodium and potassium permanganates, phosphorus pentoxide, bisulfites, etc. Preferred oxidants include KClO₄; HNO₃ and KClO₃; KMnO₄ and/or NaMnO₄; KMnO₄ and NaNO₃; K₂S₂O₈ and P₂O₅ and KMnO₄; KMnO₄ and HNO₃; and HNO₃. Preferred intercalation agents include sulfuric acid. Graphite may also be treated with intercalating agents and electrochemically oxidized. Examples of methods of making graphite oxide include those described by Staudenmaier (Ber. Stsch. Chem. Ges. (1898), 31, 1481) and Hummers (J. Am. Chem. Soc. (1958), 80, 1339).

One example of a method for the preparation of graphene sheets is to oxidize graphite to graphite oxide, which is then thermally exfoliated to form graphene sheets (also known as thermally exfoliated graphite oxide), as described in US patent application publication 2007/0092432, the disclosure of which is incorporated herein by reference. The thusly formed graphene sheets may display little or no signature corresponding to graphite or graphite oxide in their X-ray diffraction pattern.

The thermal exfoliation may be carried out in a continuous, semi-continuous batch, etc. process.

Heating can be done in a batch process or a continuous process and can be done under a variety of atmospheres, including inert and reducing atmospheres (such as nitrogen, argon, and/or hydrogen atmospheres). Heating times can range from under a few seconds or several hours or more, depending on the temperatures used and the characteristics desired in the final thermally exfoliated graphite oxide. Heating can be done in any appropriate vessel, such as a fused silica, mineral, metal, carbon (such as graphite), ceramic, etc. vessel. Heating may be done using a flash lamp.

During heating, the graphite oxide may be contained in an essentially constant location in single batch reaction vessel, or may be transported through one or more vessels during the reaction in a continuous or batch mode. Heating may be done using any suitable means, including the use of furnaces and infrared heaters.

Examples of temperatures at which the thermal exfoliation of graphite oxide may be carried out are at least about 300° C., at least about 400° C., at least about 450° C., at least about 500° C., at least about 600° C., at least about 700° C., at least about 750° C., at least about 800° C., at least about 850° C., at least about 900° C., at least about 950° C., and at least about 1000° C. Preferred ranges include between about 750 and about 3000° C., between about 850 and about 2500° C., between about 950 and about 2500° C., and between about 950 and about 1500° C.

The time of heating can range from less than a second to many minutes. For example, the time of heating can be less than about 0.5 seconds, less than about 1 second, less than about 5 seconds, less than about 10 seconds, less than about 20 seconds, less than about 30 seconds, or less than about 1 min. The time of heating can be at least about 1 minute, at least about 2 minutes, at least about 5 minutes, at least about 15 minutes, at least about 30 minutes, at least about 45 minutes, at least about 60 minutes, at least about 90 minutes, at least about 120 minutes, at least about 150 minutes, at least about 240 minutes, from about 0.01 seconds to about 240 minutes, from about 0.5 seconds to about 240 minutes, from about 1 second to about 240 minutes, from about 1 minute to about 240 minutes, from about 0.01 seconds to about 60 minutes, from about 0.5 seconds to about 60 minutes, from about 1 second to about 60 minutes, from about 1 minute to about 60 minutes, from about 0.01 seconds to about 10 minutes, from about 0.5 seconds to about 10 minutes, from about 1 second to about 10 minutes, from about 1 minute to about 10 minutes, from about 0.01 seconds to about 1 minute, from about 0.5 seconds to about 1 minute, from about 1 second to about 1 minute, no more than about 600 minutes, no more than about 450 minutes, no more than about 300 minutes, no more than about 180 minutes, no more than about 120 minutes, no more than about 90 minutes, no more than about 60 minutes, no more than about 30 minutes, no more than about 15 minutes, no more than about 10 minutes, no more than about 5 minutes, no more than about 1 minute, no more than about 30 seconds, no more than about 10 seconds, or no more than about 1 second. During the course of heating, the temperature may vary.

Examples of the rate of heating include at least about 120° C./min, at least about 200° C./min, at least about 300° C./min, at least about 400° C./min, at least about 600° C./min, at least about 800° C./min, at least about 1000° C./min, at least about 1200° C./min, at least about 1500° C./min, at least about 1800° C./min, and at least about 2000° C./min.

Graphene sheets may be annealed or reduced to graphene sheets having higher carbon to oxygen ratios by heating under reducing atmospheric conditions (e.g., in systems purged with inert gases or hydrogen). Reduction/annealing temperatures are preferably at least about 300° C., or at least about 350° C., or at least about 400° C., or at least about 500° C., or at least about 600° C., or at least about 750° C., or at least about 850° C., or at least about 950° C., or at least about 1000° C. The temperature used may be, for example, between about 750 and about 3000° C., or between about 850 and about 2500° C., or between about 950 and about 2500° C.

The time of heating can be for example, at least about 1 second, or at least about 10 seconds, or at least about 1 minute, or at least about 2 minutes, or at least about 5 minutes. In some embodiments, the heating time will be at least about 15 minutes, or about 30 minutes, or about 45 minutes, or about 60 minutes, or about 90 minutes, or about 120 minutes, or about 150 minutes. During the course of annealing/reduction, the temperature may vary within these ranges.

The heating may be done under a variety of conditions, including in an inert atmosphere (such as argon or nitrogen) or a reducing atmosphere, such as hydrogen (including hydrogen diluted in an inert gas such as argon or nitrogen), or under vacuum. The heating may be done in any appropriate vessel, such as a fused silica or a mineral or ceramic vessel or a metal vessel. The materials being heated including any starting materials and any products or intermediates) may be contained in an essentially constant location in single batch reaction vessel, or may be transported through one or more vessels during the reaction in a continuous or batch reaction. Heating may be done using any suitable means, including the use of furnaces and infrared heaters.

The graphene sheets preferably have a surface area of at least about 100 m²/g to, or of at least about 200 m²/g, or of at least about 300 m²/g, or of at least about 350 m²/g, or of at least about 400 m²/g, or of at least about 500 m²/g, or of at least about 600 m²/g., or of at least about 700 m²/g, or of at least about 800 m²/g, or of at least about 900 m²/g, or of at least about 700 m²/g. The surface area may be about 400 to about 1100 m²/g. The theoretical maximum surface area can be calculated to be 2630 m²/g. The surface area includes all values and subvalues therebetween, especially including 400, 500, 600, 700, 800, 900, 1000, 1100, 1200, 1300, 1400, 1500, 1600, 1700, 1800, 1900, 2000, 2100, 2200, 2300, 2400, 2500, and 2630 m²/g.

The graphene sheets can have number average aspect ratios of about 100 to about 100,000, or of about 100 to about 50,000, or of about 100 to about 25,000, or of about 100 to about 10,000 (where “aspect ratio” is defined as the ratio of the longest dimension of the sheet to the shortest).

Surface area can be measured using either the nitrogen adsorption/BET method at 77 K or a methylene blue (MB) dye method in liquid solution.

The dye method is carried out as follows: A known amount of graphene sheets is added to a flask. At least 1.5 g of MB are then added to the flask per gram of graphene sheets. Ethanol is added to the flask and the mixture is ultrasonicated for about fifteen minutes. The ethanol is then evaporated and a known quantity of water is added to the flask to re-dissolve the free MB. The undissolved material is allowed to settle, preferably by centrifuging the sample. The concentration of MB in solution is determined using a UV-vis spectrophotometer by measuring the absorption at λₘₐₓ=298 nm relative to that of standard concentrations.

The difference between the amount of MB that was initially added and the amount present in solution as determined by UV-vis spectrophotometry is assumed to be the amount of MB that has been adsorbed onto the surface of the graphene sheets. The surface area of the graphene sheets are then calculated using a value of 2.54 m² of surface covered per one mg of MB adsorbed.

The graphene sheets may have a bulk density of from about 0.1 to at least about 200 kg/m³. The bulk density includes all values and subvalues therebetween, especially including 0.5, 1, 5, 10, 15, 20, 25, 30, 35, 50, 75, 100, 125, 150, and 175 kg/m³.

The graphene sheets may be functionalized with, for example, oxygen-containing functional groups (including, for example, hydroxyl, carboxyl, and epoxy groups) and typically have an overall carbon to oxygen molar ratio (C/O ratio), as determined by elemental analysis of at least about 1:1, or more preferably, at least about 3:2. Examples of carbon to oxygen ratios include about 3:2 to about 85:15; about 3:2 to about 20:1; about 3:2 to about 30:1; about 3:2 to about 40:1; about 3:2 to about 60:1; about 3:2 to about 80:1; about 3:2 to about 100:1; about 3:2 to about 200:1; about 3:2 to about 500:1; about 3:2 to about 1000:1; about 3:2 to greater than 1000:1; about 10:1 to about 30:1; about 80:1 to about 100:1; about 20:1 to about 100:1; about 20:1 to about 500:1; about 20:1 to about 1000:1; about 50:1 to about 300:1; about 50:1 to about 500:1; and about 50:1 to about 1000:1. In some embodiments, the carbon to oxygen ratio is at least about 10:1, or at least about 20:1, or at least about 35:1, or at least about 50:1, or at least about 75:1, or at least about 100:1, or at least about 200:1, or at least about 300:1, or at least about 400:1, or at least 500:1, or at least about 750:1, or at least about 1000:1; or at least about 1500:1, or at least about 2000:1. The carbon to oxygen ratio also includes all values and subvalues between these ranges.

The graphene sheets may contain atomic scale kinks. These kinks may be caused by the presence of lattice defects in, or by chemical functionalization of the two-dimensional hexagonal lattice structure of the graphite basal plane.

The compositions may further comprise graphite (including natural, Kish, and synthetic, annealed, pyrolytic, highly oriented pyrolytic, etc. graphites). The ratio by weight of graphite to graphene sheets may be from about 2:98 to about 98:2, or from about 5:95 to about 95:5, or from about 10:90 to about 90:10, or from about 20:80 to about 80:20, or from about 30:70 to 70:30, or from about 40:60 to about 90:10, or from about 50:50 to about 85:15, or from about 60:40 to about 85:15, or from about 70:30 to about 85:15.

The graphene sheets may comprise two or more graphene powders having different particle size distributions and/or morphologies. The graphite may also comprise two or more graphite powders having different particle size distributions and/or morphologies.

The binders can be thermoplastics or thermosets and may be elastomers. Binders may also comprise monomers that can be polymerized before, during, or after the application of the coating to the substrate. Polymeric binders may be crosslinked or otherwise cured after the coating has been applied to the substrate. Examples of polymeric binders include polysiloxanes (such as poly(dimethylsiloxane), dimethylsiloxane/vinylmethylsiloxane copolymers, vinyldimethylsiloxane terminated poly(dimethylsiloxane), etc.), polyethers and glycols such as poly(ethylene oxide)s (also known as poly(ethylene glycol)s, poly(propylene oxide)s (also known as poly(propylene glycol)s, and ethylene oxide/propylene oxide copolymers, cellulosic resins (such as ethyl cellulose, ethyl hydroxyethyl cellulose, carboxymethyl cellulose, cellulose acetate, cellulose acetate propionates, and cellulose acetate butyrates), and poly(vinyl butyral, polyvinyl alcohol and its derivatives, ethylene/vinyl acetate polymers, acrylic polymers and copolymers (such as methyl methacrylate polymers, methacrylate copolymers, polymers derived from one or more acrylates, methacrylates, ethyl acrylates, ethyl methacrylates, butyl acrylates, butyl methacrylates and the like), styrene/acrylic copolymers, styrene/maleic anhydride copolymers, isobutylene/maleic anhydride copolymers, vinyl acetate/ethylene copolymers, ethylene/acrylic acid copolymers, polyolefins, polystyrenes, olefin and styrene copolymers, epoxy resins, acrylic latex polymers, polyester acrylate oligomers and polymers, polyester diol diacrylate polymers, UV-curable resins, and polyamides. Polyamides may be polymers and copolymers (i.e., polyamides having at least two different repeat units) having melting points between about 100 and about 255° C., or between about 120 and about 255° C., or between about 110 and about 255° C. or between about 120 and about 255° C. These include aliphatic copolyamides having a melting point of about 230° C. or less, aliphatic copolyamides having a melting point of about 210° C. or less, aliphatic copolyamides having a melting point of about 200° C. or less, aliphatic copolyamides having a melting point of about 180° C. or less, of about 150° C. or less, of about 130° C. or less, of about 120° C. or less, of about 110° C. or less, etc. Examples of these include those sold under the trade names Macromelt by Henkel, Versamid by Cognis, and Elvamide® by DuPont. Examples of suitable polymers include Elvacite® polymers supplied by Lucite International, Inc., including Elvacite® 2009, 2010, 2013, 2014, 2016, 2028, 2042, 2045, 2046, 2550, 2552, 2614, 2669, 2697, 2776, 2823, 2895, 2927, 3001, 3003, 3004, 4018, 4021, 4026, 4028, 4044, 4059, 4400, 4075, 4060, 4102, etc. Other polymer families include Bynel® polymers (such as Bynel® 2022 supplied by DuPont) and Joncryl® polymers (such as Joncryl® 678 and 682).

The coating compositions optionally comprise one or more carriers in which some or all of the components are dissolved, suspended, or otherwise dispersed or carried. Examples of suitable carriers include, but are not limited to, water, distilled or synthetic isoparaffinic hydrocarbons (such Isopar® and Norpar® (both manufactured by Exxon) and Dowanol® (manufactured by Dow), citrus terpenes and mixtures containing citrus terpenes (such as Purogen, Electron, and Positron (all manufactured by Ecolink)), terpenes and terpene alcohols (including terpineols, including alpha-terpineol), limonene, aliphatic petroleum distillates, alcohols (such as methanol, ethanol, n-propanol, i-propanol, n-butanol, i-butanol, sec-butanol, tert-butanol, pentanols, i-amyl alcohol, hexanols, heptanols, octanols, diacetone alcohol, butyl glycol, etc.), ketones (such as acetone, methyl ethyl ketone, cyclohexanone, i-butyl ketone, 2,6,8,trimethyl-4-nonanone etc.), esters (such as methyl acetate, ethyl acetate, n-propyl acetate, i-propyl acetate, n-butyl acetate, i-butyl acetate, tert-butyl acetate, carbitol acetate, etc.), glycol ethers, ester and alcohols (such as 2-(2-ethoxyethoxy)ethanol, propylene glycol monomethyl ether and other propylene glycol ethers; ethylene glycol monobutyl ether, 2-methoxyethyl ether (diglyme), propylene glycol methyl ether (PGME); and other ethylene glycol ethers; ethylene and propylene glycol ether acetates, diethylene glycol monoethyl ether acetate, 1-methoxy-2-propanol acetate (PGMEA); and hexylene glycol (such as Hexasol™ (supplied by SpecialChem)), imides, amides (such as dimethyl formamide, dimethylacetamide, etc.), cyclic amides (such as N-methylpyrrolidone and 2-pyrrolidone), lactones (such as beta-propiolactone, gamma-valerolactone, delta-valerolactone, gamma-butyrolactone, epsilon-caprolactone), cyclic imides (such as imidazolidinones such as N,N′-dimethylimidazolidinone (1,3-dimethyl-2-imidazolidinone)), and mixtures of two or more of the foregoing and mixtures of one or more of the foregoing with other carriers. Solvents may be low- or non-VOC solvents, non-hazardous air pollution solvents, and non-halogenated solvents.

The graphene sheets and graphite, if present, are preferably present in the compositions in about 1 to about 99 weight percent, in about 2 to about 99 weight percent, in about 5 to about 99 weight percent, in about 10 to about 99 weight percent in about 20 to about 99 weight percent, in about 5 to about 98 weight percent, in about 20 to about 98 weight percent, in about 30 to about 95 weight percent, in about 40 to about 95 weight percent, in about 50 to about 95 weight percent, in about 70 to about 95 weight percent, in about 80 to about 99 weight percent, in about 90 to about 99 weight percent, and in about 95 to about 99 weight percent, based on the total amount of graphene sheets and graphite, if present, and binder.

The compositions may be made using any suitable method, including wet or dry methods and batch, semi-continuous, and continuous methods.

For example, components of the coating compositions, such as one or more of the graphene sheets, graphite (if used), binders, carriers, and/or other components may be processed (e.g., milled/ground, blended, etc. by using suitable mixing, dispersing, and/or compounding techniques and apparatus, including ultrasonic devices, high-shear mixers, ball mills, attrition equipment, sandmills, two-roll mills, three-roll mills, cryogenic grinding crushers, extruders, kneaders, double planetary mixers, triple planetary mixers, high pressure homogenizers, ball mills, attrition equipment, sandmills, horizontal and vertical wet grinding mills, etc. Processing (including grinding) technologies can be wet or dry and can be continuous or discontinuous. Suitable materials for use as grinding media include metals, carbon steel, stainless steel, ceramics, stabilized ceramic media (such as yttrium stabilized zirconium oxide), PTFE, glass, tungsten carbide, etc. Methods such as these can be used to change the particle size and/or morphology of the graphite, graphene sheets, other components, and blends or two or more components.

Components may be processed together or separately and may go through multiple processing (including mixing/blending) stages, each involving one or more components (including blends).

There is no particular limitation to the way in which the graphene sheets, graphite (if used), and other components are processed and combined. For example, graphene sheets and/or graphite may be processed into given particle size distributions and/or morphologies separately and then combined for further processing with or without the presence of additional components. Unprocessed graphene sheets and/or graphite may be combined with processed graphene sheets and/or graphite and further processed with or without the presence of additional components. Processed and/or unprocessed graphene sheets and/or processed and/or unprocessed graphite may be combined with other components, such as one or more binders and then combined with processed and/or unprocessed graphene sheets and/or processed and/or unprocessed graphite. Two or more combinations of processed and/or unprocessed graphene sheets and/or processed and/or unprocessed graphite that have been combined with other components may be further combined or processed.

In one embodiment, if a multi-chain lipid is used, it is added to graphene sheets (and/or graphite if present) before processing.

After blending and/or grinding steps, additional components may be added to the compositions, including, but not limited to, thickeners, viscosity modifiers, binders, etc. The compositions may also be diluted by the addition of more carrier.

The compositions may optionally comprise one or more additional additives, such as dispersion aids (including surfactants, emulsifiers, and wetting aids), adhesion promoters, thickening agents (including clays), defoamers and antifoamers, biocides, additional fillers, flow enhancers, stabilizers, crosslinking and curing agents, etc.

Examples of dispersing aids include glycol ethers (such as poly(ethylene oxide), block copolymers derived from ethylene oxide and propylene oxide (such as those sold under the trade name Pluronic® by BASF), acetylenic diols (such as 2,5,8,11-tetramethyl-6-dodecyn-5,8-diol ethoxylate and others sold by Air Products under the trade names Surfynol® and Dynol®), salts of carboxylic acids (including alkali metal and ammonium salts), and polysiloxanes.

Examples of grinding aids include stearates (such as Al, Ca, Mg, and Zn stearates) and acetylenic diols (such as those sold by Air Products under the trade names Surfynol® and Dynol®).

Examples of adhesion promoters include titanium chelates and other titanium compounds such as titanium phosphate complexes (including butyl titanium phosphate), titanate esters, diisopropoxy titanium bis(ethyl-3-oxobutanoate, isopropoxy titanium acetylacetonate, and others sold by Johnson-Matthey Catalysts under the trade name Vertec.

Examples of thickening agents include glycol ethers (such as poly(ethylene oxide), block copolymers derived from ethylene oxide and propylene oxide (such as those sold under the trade name Pluronic® by BASF), long-chain carboxylate salts (such aluminum, calcium, zinc, etc. salts of stearates, oleats, palmitates, etc.), aluminosilicates (such as those sold under the Minex® name by Unimin Specialty Minerals and Aerosil® 9200 by Evonik Degussa), fumed silica, natural and synthetic zeolites, etc.

The compositions may optionally comprise at least one “multi-chain lipid”, by which term is meant a naturally-occurring or synthetic lipid having a polar head group and at least two nonpolar tail groups connected thereto. Examples of polar head groups include oxygen-, sulfur-, and halogen-containing, phosphates, amides, ammonium groups, amino acids (including α-amino acids), saccharides, polysaccharides, esters (Including glyceryl esters), zwitterionic groups, etc.

The tail groups may be the same or different. Examples of tail groups include alkanes, alkenes, alkynes, aromatic compounds, etc. They may be hydrocarbons, functionalized hydrocarbons, etc. The tail groups may be saturated or unsaturated. They may be linear or branched. The tail groups may be derived from fatty acids, such as oleic acid, palmitic acid, stearic acid, arachidic acid, erucic acid, arachadonic acid, linoleic acid, linolenic acid, oleic acid, etc.

Examples of multi-chain lipids include, but are not limited to, lecithin and other phospholipids (such as phosphoglycerides (including phosphatidylserine, phosphatidylinositol, phosphatidylethanolamine (cephalin), and phosphatidylglycerol) and sphingomyelin); glycolipids (such as glucosyl-cerebroside); saccharolipids; sphingolipids (such as ceramides, di- and triglycerides, phosphosphingolipids, and glycosphingolipids); etc. They may be amphoteric, including zwitterionic.

The compositions may optionally comprise one or more charged organic compounds. The charged organic compound comprises at least one ionic functional group and one hydrocarbon-based chain. Examples of ionic functional groups include ammonium salts, sulfates, sulphonates, phosphates, carboxylates, etc. If two or more ionic functional groups are present, they may be of the same or different types. The compound may comprise additional functional groups, including, but not limited to hydroxyls, alkenes, alkynes, carbonyl groups (such as carboxylic acids, esters, amides, ketones, aldehydes, anhydrides, thiol, etc.), ethers, fluoro, chloro, bromo, iodo, nitriles, nitrogen containing groups, phosphorous containing groups, silicon containing groups, etc.

The compound comprises at least one hydrocarbon-based chain. The hydrocarbon-based chain may be saturated or unsaturated and may be branched or linear. It may be an alkyl group, alkenyl group, alkynyl group, etc. It need not contain only carbon and hydrogen atoms. It may be substituted with other functional groups (such as those mentioned above). Other functional groups, such as esters, ethers, amides, may be present in the length of the chain. In other words, the chain may contain two or more hydrocarbon-based segments that are connected by one or more functional groups. In one embodiment, at least one ionic functional group is located at the end of a chain.

Examples of ammonium salts include materials having the formula: R¹R²R³R⁴N⁺X⁻, where R¹, R², and R³, are each independently H, a hydrocarbon-based chain, an aryl-containing group, an alicyclic group; an oligomeric group, a polymeric group, etc.; where R⁴ is a hydrocarbon-based chain having at least four carbon atoms; and where X⁻ is an anion such as fluoride, bromide, chloride, iodide, sulfate, hydroxide, carboxylate, etc. Any of the R groups may have one or more additional ammonium groups.

Examples of R groups include methyl, ethyl, propyl, butyl, pentyl, hexyl, heptyl, octyl, nonyl, decyl, undecyl, dodecyl, tridecyl, tetradecyl, pentadecyl, hexadecyl, heptadecyl, octadecyl, nonadecyl, eicosyl, C₂₁ to C₄₀ chains, etc.

Examples of quaternary ammonium salts include tetraalkylammonium salts, dialkyldimethylammonium salts, alkyltrimethylammonium salts, where the alkyl groups are one or more groups containing at least eight carbon atoms. Examples include tetradodecylammonium, tetradecyltrimethylammonium halide, hexadecyltrimethylammonium halide, didodecyldimethylammonium halide, etc.

Ammonium salts may be bis- or higher order ammonium salts, including quaternary ammonium salts. They may be salts of carboxylic acids, dicarboxylic acids, tricarboxylic acids, and higher carboxylic acids. The carboxylic acids may have be part of a hydrocarbon-based chain having at least about four linear carbon atoms. Examples include ammonium salts of octanoic acid, nonanoic acid, decanoic acid, undecanoic acid, dodecanoic acid, tridecanoic acid, tetradecanoic acid, pentadecanic acid, carboxylic acids having at least 15 carbon atoms, stearic acid, oleic acid, montanic acid, apidic acid, 1,7-heptanedioic acid, 1,8-octandioic acid, 1,9-nonanedioic acid, sebacic acid, 1,11-undecandioic acid, 1,12-dodecanedioic acid, 1,13-tridecanedioic acid, 1,14-tetradecanedioic acid, 1,15-pentadecanedioic acid, 1,16-hexadecanedioic acid, 1,17-heptadecanedioic acid, 1,18-octadecanedioic acid, 1,19-nonadecanedioic acid, 1,20-eicosanedioic acid, dicarboxylic acids having 21 to 40 carbon atoms, etc.

Alkylol ammonium salts of carboxylic acids (including high molecular weight carboxylic acids and unsaturated carboxylic acids) may be used. Examples include EFKA 5071, an alkylol ammonium salt of a high-molecular weight carboxylic acid supplied by Ciba and BYK-ES80, an alkylolammonium salt of an unsaturated acidic carboxylic acid ester manufactured by BYK USA, Wallingford, Conn.

The charged organic compound may have a sulfur containing group such as a sulphonate, mesylate, triflate, tosylate, besylate, sulfates, sulfite, peroxomonosulfate, peroxodisulfate, pyrosulfate, dithionate, metabisulfite, dithionite, thiosulfate, tetrathionate, etc. The organic compound may also contain two or more sulfur containing groups.

Alkyl, alkenyl, and/or alkynyl sulfates and sulphonates are preferred sulfur-containing compounds. The alkyl, alkenyl, and/or alkynyl groups preferably contain at least about 8 carbon atoms, or more preferably at least about 10 carbon atoms. Examples include decylsulfate salts, dodecylsulfate salts (such as sodium 1-dodecanesulfate (SDS)), decylsulfonate salts, dodecylsulfonate salts (such as sodium 1-dodecanesulfonate (SDSO)), etc. The counter ions may be any suitable cation, such as lithium, sodium, potassium, ammonium, etc.

The charged organic compound may be present in about 1 to about 75 weight percent, in about 2 to about 70 weight percent, in about 2 to about 60 weight percent, in about 2 to about 50 weight percent, in about 5 to about 50 weight percent, in about 10 to about 50 weight percent, in about 10 to about 40 weight percent, in about 20 to about 40 weight percent, based on the total weight of charged organic compound and graphene sheets and other carbonaceous fillers, if used.

The compositions may optionally contain additional electrically conductive components other than the graphene sheets, such as metals (including metal alloys), conductive metal oxides, polymers, carbonaceous materials other than compositions, metal-coated materials, etc. These components can take a variety of forms, including particles, powders, flakes, foils, needles, etc.

Examples of metals include, but are not limited to silver, copper, aluminum, platinum, palladium, nickel, chromium, gold, bronze, colloidal metals, etc. Examples of metal oxides include antimony tin oxide and indium tin oxide and materials such as fillers coated with metal oxides. Metal and metal-oxide coated materials include, but are not limited to metal coated carbon and graphite fibers, metal coated glass fibers, metal coated glass beads, metal coated ceramic materials (such as beads), etc. These materials can be coated with a variety of metals, including nickel.

Examples of electrically conductive polymers include, but are not limited to, polyacetylene, polyethylene dioxythiophene (PEDOT), poly(styrenesulfonate) (PSS), PEDOT:PSS copolymers, polythiophene and polythiophenes, poly(3-alkylthiophenes), poly(2,5-bis(3-tetradecylthiophen-2-yl)thieno[3,2-b]thiophene) (PBTTT), poly(phenylenevinylene), polypyrene, polycarbazole, polyazulene, polyazepine, polyfluororenes, polynaphthalene, polyisonaphthalene, polyaniline, polypyrrole, poly(phenylene sulfide), copolymers of one or more of the foregoing, etc., and their derivatives and copolymers. The conductive polymers may be doped or undoped. They may be doped with boron, phosphorous, iodine, etc.

Examples of carbonaceous materials other than graphene sheets and graphite include, but are not limited to, graphitized carbon, carbon black, carbon fibers and fibrils, carbon whiskers, vapor-grown carbon nanofibers, metal coated carbon fibers, carbon nanotubes (including single- and multi-walled nanotubes), fullerenes, activated carbon, carbon fibers, expanded graphite, expandable graphite, graphite oxide, hollow carbon spheres, carbon foams, etc.

The compositions can be applied to a wide variety of substrates, including, but not limited to, glass (including silicon dioxide), fluorine doped tin oxide (FTO) glass, FTO and FTO-containing substrates, indium tin oxide (ITO) and ITO-containing substrates, zirconium oxide and zirconium oxide-containing substrates, zinc oxide and zinc oxide-containing substrates, hole-conducting films, such as those formed from or containing spirobifluorene dyes such as spiro-OMeTAD (2,2′,7,7′-tetrakis(N,N-di-p-methoxypheny-amine)-9,9′-spirobifluorene), electron conducting films, flexible and/or stretchable materials, silicones and other elastomers and other polymeric materials, metals (such as aluminum, copper, steel, stainless steel, etc.), adhesives, fabrics (including cloths) and textiles (such as cotton, wool, polyesters, rayon, etc.), clothing, glasses and other minerals, ceramics, silicon surfaces, wood, paper, cardboard, paperboard, cellulose-based materials, glassine, labels, silicon and other semiconductors, laminates, corrugated materials, concrete, bricks, and other building materials, etc. Substrates may in the form of films, papers, wafers, larger three-dimensional objects, etc.

The substrates may have been treated with other coatings (such as paints) or similar materials before the compositions are applied. Examples include substrates (such as PET) coated with indium tin oxide, antimony tin oxide, etc. They may be woven, nonwoven, in mesh form; etc. They may be woven, nonwoven, in mesh form; etc.

The substrates may be paper-based materials generally (including paper, paperboard, cardboard, glassine, etc.). Paper-based materials can be surface treated. Examples of surface treatments include coatings such as polymeric coatings, which can include PET, polyethylene, polypropylene, acetates, nitrocellulose, etc. Coatings may be adhesives. The paper based materials may be sized.

Examples of polymeric materials include, but are not limited to, those comprising thermoplastics and thermosets, including elastomers and rubbers (including thermoplastics and thermosets), silicones, fluorinated polysiloxanes, natural rubber, butyl rubber, chlorosulfonated polyethylene, chlorinated polyethylene, styrene/butadiene copolymers (SBR), styrene/ethylene/butadiene/stryene copolymers (SEBS), styrene/ethylene/butadiene/stryene copolymers grafted with maleic anhydride, styrene/isoprene/styrene copolymers (SIS), polyisoprene, nitrile rubbers, hydrogenated nitrile rubbers, neoprene, ethylene/propylene copolymers (EPR), ethylene/propylene/diene copolymers (EPDM), ethylene/vinyl acetate copolymer (EVA), hexafluoropropylene/vinylidene fluoride/tetrafluoroethylene copolymers, tetrafluoroethylene/propylene copolymers, fluorelastomers, polyesters (such as poly(ethylene terephthalate) (PET), poly(butylene terephthalate), poly(ethylene naphthalate), liquid crystalline polyesters, poly(lactic acid), etc.); polystyrene; polyamides (including polyterephthalamides); polyimides (such as Kapton®); aramids (such as Kevlar® and Nomex®); fluoropolymers (such as fluorinated ethylene propylene (FEP), polytetrafluoroethylene (PTFE), poly(vinyl fluoride), poly(vinylidene fluoride), Viton® grades, etc.); polyetherimides; poly(vinyl chloride); poly(vinylidene chloride); polyurethanes (such as thermoplastic polyurethanes (TPU); spandex, cellulosic polymers (such as nitrocellulose, cellulose acetate, etc.); styrene/acrylonitriles polymers (SAN); arcrylonitrile/butadiene/styrene polymers (ABS); polycarbonates; polyacrylates; poly(methyl methacrylate); ethylene/vinyl acetate copolymers; thermoset epoxies and polyurethanes; polyolefins (such as polyethylene (including low density polyethylene, high density polyethylene, ultrahigh molecular weight polyethylene, etc.), polypropylene (such as biaxially-oriented polypropylene, etc.); Mylar; etc. They may be non-woven materials, such as DuPont Tyvek®. They may be adhesive materials. The substrate may be a transparent or translucent or optical material, such as glass, quartz, polymer (such as polycarbonate or poly(meth)acrylates (such as poly(methyl methacrylate).

The compositions may be applied to the substrate using any suitable method, including, but not limited to, painting, pouring, spin casting, solution casting, dip coating, powder coating, by syringe or pipette, spray coating, curtain coating, lamination, co-extrusion, electrospray deposition, ink-jet printing, spin coating, thermal transfer (including laser transfer) methods, doctor blade printing, screen printing, rotary screen printing, gravure printing, lithographic printing, intaglio printing, digital printing, capillary printing, offset printing, electrohydrodynamic (EHD) printing (a method of which is described in WO 2007/053621, which is hereby incorporated herein by reference), flexographic printing, pad printing, stamping, xerography, microcontact printing, dip pen nanolithography, laser printing, via pen or similar means, etc. The compositions can be applied in multiple layers.

After they have been applied to a substrate, the coating compositions may be cured using any suitable technique, including drying and oven-drying (in air or another inert or reactive atmosphere), UV curing, IR curing, drying, crosslinking, thermal curing, laser curing, microwave curing or drying, sintering, and the like to form the electrode.

The thermal curing temperature may be any suitable temperature given the binder, substrate, solvent system, etc. In some embodiments, the curing may take place at a temperature of no more than about 135° C., or no more than about 120° C., or no more than about 110° C., or no more than about 100° C., or no more than about 90° C., or no more than about 80° C., or no more than about 70° C.

The electrodes can be electrically conductive. They can have conductivities of at least about 10⁻⁸ S/m. They can have a conductivities of about 10⁻⁶ S/m to about 10⁵ S/m, or of about 10⁻⁵ S/m to about 10⁵ S/m. In other embodiments of the invention, the electrodes have conductivities of at least about 0.001 S/m, of at least about 0.01 S/m, of at least about 0.1 S/m, of at least about 1 S/m, of at least about 10 S/m, of at least about 100 S/m, or at least about 1000 S/m, or at least about 10,000 S/m, or at least about 20,000 S/m, or at least about 30,000 S/m, or at least about 40,000 S/m, or at least about 50,000 S/m, or at least about 60,000 S/m, or at least about 75,000 S/m, or at least about 10⁵ S/m, or at least about 10⁶ S/m.

In some embodiments, the surface resistivities of the electrodes may be no greater than about 500 Ω/square, or no greater than about 350 Ω/square, or no greater than about 200 Ω/square, or no greater than about 150 Ω/square, or no greater than about 100 Ω/square, or no greater than about 75 Ω/square, or no greater than about 50 Ω/square, or no greater than about 30 Ω/square, or no greater than about 20 Ω/square, or no greater than about 10 Ω/square, or no greater than about 5 Ω/square, or no greater than about 1 Ω/square, or no greater than about 0.1 Ω/square, or no greater than about 0.01 Ω/square, or no greater than about 0.001 Ω/square.

The electrodes may be incorporated into DSSCs using any suitable method, including using a thermomelt sealant such as Surlyn® or Bynel® from DuPont, or being coated directly on the hole conducting material. The electrode can be used with any appropriate and compatible hole conductor system, such as an electrolyte system with a redox couple (such as iodide/triiodide, cobalt complexes, such as Co^{II} and Co^{III} complexes, including Co^{II/III}[(dbbip)₂](ClO₄)₂, and the like, (SeCN)⁻₃/SeCN⁻, ferrocene/ferrocenium all with or without gelators), solid-state hole conductor materials (such as spiro-OMeTAD (2,2′,7,7′-tetrakis(N,N-di-p-methoxypheny-amine)-9,9′-spirobifluorene), ionic liquids, or molten salts. The hole conductor may also be one or more electrically conductive polymers (such those described above). The electrodes may in used in DSSCs in conjunction with a second electrode (which can act as a cathode). The second electrode can contain a platinum catalyst on its surface and/or inside.

The conductivity and catalytic activity of the coating allow for an arbitrary substrate to be used, including those which are low cost and flexible.

In some embodiments, the cells may have a power conversion efficiency of at least about 3%, or at least about 4%, or at least about 5%, or at least about 6%, or at least about 10%.

The solar cells may be monolithic solar cells, wherein the electrodes, hole conductor, and a spacer are laminated together.

### EXAMPLES

### Examples 1 and 2 and Comparative Example 1

### Construction of DSSCs

DSSCs were constructed as described previously in the literature (Journal of the American Chemical Society 1993, 115, (14), 6382-6390). In brief, 2 g of P25 titania nanoparticles (Evanonik) were suspended with 66 μL of acetylacetone and 3.333 mL deionized water. Titania films, four layers thick, were cast on fluorine-doped tin oxide glass (FTO) using a scotch tape mask and a glass rod via the doctor blade technique. These films were then heated to 485° C. for 30 min in air. The resulting electrode was immersed in a 0.3 mM N3 dye—ethanol (Acros) solution for 20 h to form the sensitized photocathode.

In the case of Comparative Example 1, the counter electrode was a thermally treated chloroplatinic acid electrode prepared on FTO. 2 μL of 5 mM chloroplatinic acid in isopropanol was drop cast on an FTO electrode with a 0.39 cm² mask. The sample was then heated to 380° C. for 20 min before use.

In the cases of Examples 1 and 2, the counter electrodes were formed by coating an electrically conductive ink comprising graphene sheets, an acrylate binder, and a solvent onto a poly(ethylene terephthalate) substrate and curing it at about 120° C. for about 4 minutes. In the case of Example 1, the electrode had a surface resistivity of about 9-10 Ohm/square and in the case of Example 2, the electrode had a surface resistivity of less than about 5 Ohm/square.

Due to the flexible nature of the films of Examples 1 and 2, to prevent short-circuiting of the cells, the electrodes were separated by 100 μm thick laboratory tape (Fisher) and clamped together using binder clips. An electrolyte using the iodide/triiodide redox couple in an organic solvent (Iodolyte AN-50 from Solaronix) was added. Cells were tested immediately after fabrication.

### Measurements

Current-voltage characteristics of DSSCs were taken under AM1.5G light, simulated at 100 mW/cm² with a 16S solar simulator (SolarLight) using a potentiostat (Biologic SP-150) to apply various loads.

The results are given in Table 1 and are the average of 3 identically prepared samples. V_{oc} refers to the open circuit voltage. J_{sc} refers to the short circuit current density. η refers to cell efficiency (the cell's maximum power output divided by the input power, per area). FF refers to the fill factor, which is the ratio of the maximum power obtainable in the device to the theoretical maximum power [FF=(J*×V*)/(J_{sc}×V_{oc}), where J* and V* are the current density and voltage, respectively, at the cell's maximum power output].

TABLE 1

| | V_{oc} (V) | J_{sc} (mA cm⁻²) | FF | η (%) |
|---|---|---|---|---|
| Example 1 | 0.70 | 8.14 | 0.66 | 3.75 |
| Example 2 | 0.71 | 7.77 | 0.70 | 3.83 |
| Comparative | 0.73 | 7.89 | 0.72 | 4.16 |
| Example 1 | | | | |

### Examples 3 and 4 and Comparative Example 2

### Construction of DSSCs

In Examples 3 and 4, and Comparative Example 2 the DSSCs were created using commercial titania pastes similarly to mentioned in the literature (Journal of the American Chemical Society 2010, 132, (46), 16714-16724). Cleaned FTO conducting glass substrates were pretreated by immersion in a 40 mM aqueous TiCl₄ solution at 70° C. for 30 min and then washed with water. Titania films were prepared with an area of 0.25 cm² by repeatedly screen printing Dyesol DSL 18 NR-T colloidal titania paste and drying at 300° C. between layers. A light-scattering titania layer (PST-400C, JGC Catalysts and Chemical Ltd.) was deposited on top of the titania film. The electrodes were then heated at 180 (10 min), 320 (10 min), 390 (10 min), and 500° C. (60 min). After sintering, the electrodes were immersed in aqueous TiCl₄ and rinsed as above. A second and final heating step, at 500° C. for 60 min, was performed. The resulting electrode was immersed in a 0.3 mM D29 organic dye-ethanol solution for 20 h to form the sensitized photocathode.

In the case of Comparative Example 2, the counter electrode is a thermally treated chloroplatinic acid electrode prepared on FTO prepared. 21 μL of 4.8 mM chloroplatinic acid in ethanol was drop cast on a 2.25 cm² FTO electrode. The sample was then heated to 400° C. for 20 min.

In the cases of Examples 3 and 4, the counter electrodes were formed by coating electrically conductive inks comprising graphene sheets, an acrylate binder, and a solvent onto a FTO substrate and curing it at about 120° C. for about 4 minutes. In the case of Example 3 the electrode was about 15 μm thick. In the case of Example 4 the electrode was about 6 μm thick.

A 50 μm thermoplastic Suryln spacer was used to seal the edges of the solar cells. An electrolyte solution using the iodide/triiodide redox couple (0.6 M tetrabutyl ammonium iodide, 0.1M Lil, 0.05 M I₂ and 0.2M 4-tert butylpyridine in acetonitrile) was introduced through two holes predrilled in the counter electrode, and the cell was sealed with Surlyn covers and a glass coverslip.

### Measurements

Current-voltage characteristics of DSSCs were taken under AM1.5G light, simulated at 100 mW/cm² with a solar simulator (Newport model 91160) using a source meter (Keithley 2400).

The results are given in Table 2 and are the average of two identically prepared samples. V_{oc} refers to the open circuit voltage. J_{sc} refers to the short circuit current density. η refers to cell efficiency (the cell's maximum power output divided by the input power, per area). FF refers to the fill factor, which is the ratio of the maximum power obtainable in the device to the theoretical maximum power [FF=(J*×V*)/(J_{sc}×V_{oc}), where J* and V* are the current density and voltage, respectively, at the cell's maximum power output].

TABLE 2

| | V_{oc} (V) | J_{sc} (mA cm⁻²) | FF | η (%) |
|---|---|---|---|---|
| Example 3 | 0.70 | 8.5 | 0.73 | 4.4 |
| Example 4 | 0.75 | 8.7 | 0.66 | 4.3 |
| Comparative | 0.76 | 10.0 | 0.66 | 5.0 |
| Example 2 | | | | |

### Examples 5-10 and Comparative Example 3

To determine the catalytic activity of the electrodes, electrochemical impedance spectroscopy (EIS) was performed on the electrodes using a sandwich cell configuration as described in the literature (Electrochimica Acta 2001 46 (22), 3457, and ACS Nano 2010 4 (10) 6203-6211). Symmetric graphene ink electrodes (Examples 5-10) and symmetric platinum coated FTO electrodes (Comparative Example 2) were tested in an acetonitrile electrolyte containing 0.6 M tetrabutyl ammonium iodide, 0.1M Lil, 0.05 M I₂ and 0.2M 4-tert butylpyridine. A 50 μm thick Surlyn® film was used to separate electrodes and seal the cells. EIS measurements were taken at 0 V. The magnitude of the alternating signal was 10 mV, and the frequency range was 1 Hz to 100 kHz. Zview software, with the appropriate equivalent circuit, in which the high and mid-frequency humps from about 100,000 to about 25 Hz represents the charge transfer resistance (R_{CT}), was used to analyze the impendence spectra and determine R_{CT} of the electrodes. The results are given in Table 3.

In the cases of Examples 5 through 10, the counter electrodes were formed by coating electrically conductive inks comprising graphene sheets, an acrylate binder, and a solvent onto a fluorine doped tin oxide substrate and curing it at about 120° C. for about 4 minutes. In the case of Examples 5, 6, and 7 (which used one ink), the dried ink had a bulk conductivity of about 65 S/m and in the case of Examples 8, 9, and 10 (which used a second ink), the dried ink had a bulk conductivity of 100 S/m.

TABLE 3

| | Thickness | R_{CT} value |
|---|---|---|
| | (μm) | (Ohm cm²) |
| Example 5 | 3 | 12.4 |
| Example 6 | 10 | 2.4 |
| Example 7 | 15 | 0.9 |
| Example 8 | 2 | 16.5 |
| Example 9 | 6 | 3.8 |
| Example 10 | 10 | 5.9 |
| Comparative | not applicable | 1.1 |
| Example 3 | | |

1. A solar cell electrode, comprising a composition comprising graphene sheets and at least one binder.

2. The electrode of claim 1, in the form of a dye-sensitized solar cell electrode.

3. The electrode of claim 1, in the form of a catalytic counter electrode.

4. The electrode of claim 1, wherein the composition is adhered to a substrate.

5. The electrode of claim 1, wherein the composition further comprises graphite.

6. The electrode of claim 1, wherein the graphene sheets have a surface area of at least about 300 m²/g.

7. The electrode of claim 1, wherein the graphene sheets have a carbon to oxygen molar ratio of at least about 10:1.

8. The electrode of claim 1, wherein the graphene sheets have a carbon to oxygen molar ratio of at least about 75:1.

9. The electrode of claim 1, wherein the substrate is flexible.

10. The electrode of claim 1, wherein at least a portion of its surface has a resistivity of no greater than about 100 Ω/square.

11. The electrode of claim 1, wherein at least a portion of its surface has a resistivity of no greater than about 25 Ω/square.

12. A method of making a dye-sensitized solar cell electrode, comprising incorporating an electrode comprising a composition comprising graphene sheets and at least one binder into a solar cell.

13. The method of claim 12, wherein the composition is coated onto a substrate to form the electrode.

14. The method of claim 12, wherein the graphene sheets have a surface area of at least about 300 m²/g.

15. The method of claim 12, wherein the graphene sheets have a surface area of at least about 400 m²/g.

16. The method of claim 12, wherein the graphene sheets have a carbon to oxygen molar ratio of at least about 10:1.

17. The method of claim 12, wherein the graphene sheets have a carbon to oxygen molar ratio of at least about 50:1.

18. The method of claim 12, wherein at least a portion of the surface of the electrode has a resistivity of no greater than about 25 Ω/square

19. A dye-sensitized solar cell comprising the electrode of claim 1.

20. The dye-sensitized solar call of claim 19, in the form of a monolithic solar cell.
